(19) United States
(12) Patent Application Publication
(10) Pub. No.: US 2024/0234278 A9
(43) Pub. Date: Jul. 11, 2024

(54) INTERCONNECT SUBSTRATE, METHOD OF MAKING THE SAME, AND SEMICONDUCTOR APPARATUS

(71) Applicant: SHINKO ELECTRIC INDUSTRIES CO., LTD., Nagano (JP)

(72) Inventors: Kei MURAYAMA, Nagano (JP); Mitsuhiro AIZAWA, Nagano (JP)

(21) Appl. No.: 18/489,288

(22) Filed: Oct. 18, 2023

(30) Foreign Application Priority Data
Oct. 24, 2022 (JP) 2022-169630

(51) Int. Cl. H01L 23/498; H01L 21/48; H01L 23/00; H01L 23/538

(52) U.S. Cl. CPC H01L 23/49822; H01L 21/486; H01L 23/538; H01L 24/81; H01L 2224/81801; H01L 2924/014

(57) ABSTRACT

An interconnect substrate includes an insulating layer, an electrode disposed on the insulating layer and having a first surface not covered with the insulating layer, and an external connection terminal disposed on the first surface of the electrode, wherein the electrode has a recess in the first surface, wherein the external connection terminal includes a first conductor filling the recess and a second conductor disposed on the first conductor, and a melting point of the first conductor is higher than a melting point of the second conductor, and wherein a metal material of the electrode is different from a metal material of the first conductor.

### CROSS-REFERENCE TO RELATED APPLICATIONS

The present application is based on and claims priority to Japanese Patent Application No. 2022-169630 filed on Oct. 24, 2022, with the Japanese Patent Office, the entire contents of which are incorporated herein by reference.

### FIELD

The disclosures herein relate to interconnect substrates, methods of making the same, and semiconductor apparatuses.

### BACKGROUND

External connection terminals are provided on the pads of an interconnect substrate for connection to a semiconductor chip or the like. As the material of external connection terminals, solder, for example, may be used. An external connection terminal is formed by, for example, printing a solder paste on the upper surface of a pad and reflowing the solder paste (see Patent Document 1, for example).

In some cases, a recess may be formed in the upper surface of a pad depending on the conditions and the like of forming the pad. When an external connection terminal is formed in the upper surface of such a pad, a material such as solder paste does not sufficiently fill the recess, which results in the formation of a void in the external connection terminal. With the formation of a void, it is difficult to ensure reliable connection between the interconnect substrate and a semiconductor chip.

Accordingly, there may be a need for an interconnect substrate for which the reliability of connection with a semiconductor chip is improved.

### PRIOR ART DOCUMENT

### Patent Document

[Patent Document 1] Japanese Laid-Open Patent Publication No. 2003-179334

### SUMMARY

According to an aspect of the embodiment, an interconnect substrate includes an insulating layer, an electrode disposed on the insulating layer and having a first surface not covered with the insulating layer, and an external connection terminal disposed on the first surface of the electrode, wherein the electrode has a recess in the first surface, wherein the external connection terminal includes a first conductor filling the recess and a second conductor disposed on the first conductor, and a melting point of the first conductor is higher than a melting point of the second conductor, and wherein a metal material of the electrode is different from a metal material of the first conductor.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a partial cross-sectional view illustrating an example of an interconnect substrate according to a first embodiment;

FIGS. 2A through 2C are drawings illustrating an example of the steps of making the interconnect substrate according to the first embodiment;

FIGS. 3A through 3C are drawings illustrating the example of the steps of making the interconnect substrate according to the first embodiment;

FIG. 4 is a partial cross-sectional view illustrating an example of an interconnect substrate according to a comparative example;

FIG. 5 is a partial cross-sectional view illustrating an example of an interconnect substrate according to a first variation of the first embodiment;

FIG. 6 is a partial cross-sectional view illustrating an example of an interconnect substrate according to a second variation of the first embodiment;

FIG. 7 is a cross-sectional view illustrating an example of a semiconductor apparatus according to a first example of application of the first embodiment;

FIG. 8 is a cross-sectional view illustrating an example of a semiconductor apparatus according to a second example of application of the first embodiment; and

FIGS. 9A and 9B are drawings illustrating the flows of current.

### DESCRIPTION OF EMBODIMENTS

In the following, embodiments of the present invention will be described with reference to the accompanying drawings.

In the following, embodiments for carrying out the invention will be described with reference to the accompanying drawings. In the drawings, the same elements are referred to by the same reference numerals, and a duplicate description thereof may be omitted.

### First Embodiment

### [Structure of Interconnect Substrate]

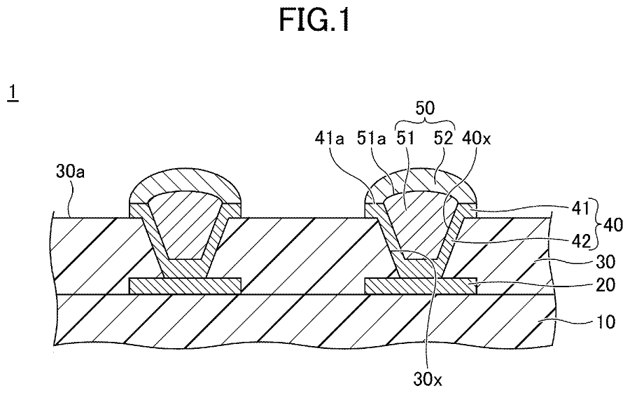

FIG. 1 is a partial cross-sectional view illustrating an example of an interconnect substrate according to a first embodiment. Referring to FIG. 1, an interconnect substrate 1 includes an insulating layer 10, an interconnect layer 20, an insulating layer 30, an electrode 40, and an external connection terminal 50. The interconnect substrate 1 may be coreless, or may have a core.

In the first embodiment, for the sake of convenience, the same side of the interconnect substrate 1 as the insulating layer 30 is referred to as an upper side, and the same side thereof as the insulating layer 10 is referred to as a lower side. A surface of an object on the upper side is referred to as an upper surface, and a surface thereof on the lower side is referred to as a lower surface. However, the interconnect substrate 1 may be used upside down, or may be arranged at an any angle. In addition, a plan view refers to a view of an object as seen in the normal direction of an upper surface 30a of the insulating layer 30, and a plane shape refers to the shape of an object viewed in the normal direction of the upper surface 30a of the insulating layer 30.

The insulating layer 10 may be formed by, for example, a build-up method as an interlayer insulating layer in a multilayer interconnect structure. An additional interconnect layer and an additional insulating layer may be stacked as lower layers under the insulating layer 10. In such a case, via holes may be provided through the insulating layer 10 and the additional insulating layer, and interconnect layers may be connected to each other through via interconnects provided in the via holes.

The material of the insulating layer 10 may be, for example, an epoxy-based insulating resin, a polyimide-based insulating resin, or the like that is a non-photosensitive (thermosetting) resin. Alternatively, the material of the insulating layer 10 may be, for example, an epoxy-based insulating resin, an acrylic-based insulating resin, or the like that is a photosensitive resin. The insulating layer 10 may include a reinforcing material such as glass cloth. Further, the insulating layer 10 may contain a filler such as silica (SiO₂). The thickness of the insulating layer 10 may be, for example, about 10 μm to 100 μm.

The interconnect layer 20 is formed on the insulating layer 10. The material of the interconnect layer 20 may be, for example, copper (Cu) or the like. The thickness of the interconnect layer 20 may be, for example, about 10 μm to 200 μm. The interconnect layer 20 may have a laminated structure comprised of a plurality of metal layers.

The insulating layer 30 is formed on the insulating layer 10 such as to cover the upper surface and the side surface of the interconnect layer 20. As the material of the insulating layer 30, an insulating resin similar to that of the insulating layer 10 may be used. The thickness of the insulating layer 30 may be, for example, substantially the same as that of the insulating layer 10. The insulating layer 30 may contain a filler such as silica (SiO₂).

The electrodes 40 include a pad 41 provided on the upper surface 30a of the insulating layer 30 and a through interconnect 42 connected to the pad 41 and provided in the insulating layer 30. The upper surface 41a and side surface of the pad 41 are not covered with the insulating layer 30, and the lower surface of the pad 41 is in contact with the upper surface 30a of the insulating layer 30. The thickness of the pad 41 may be, for example, about 10 μm to 200 μm.

The through interconnect 42 is structured to cover the inner wall of a via hole 30x that extends through the insulating layer 30 and to expose the upper surface of the interconnect layer 20. The via hole 30x may be a recess having an inverted truncated conical shape with the diameter of the upper opening toward the pad 41 being larger than the diameter of the bottom opening at the upper surface of the interconnect layer 20. The diameters of the openings of the via hole 30x may be, for example, about 5 μm to 30 μm.

The pad 41 is electrically connected to the interconnect layer 20 via the through interconnect 42. The pad 41 and the through interconnect 42 may be seamlessly formed with each other. In addition to the pad 41, additional pads and interconnect patterns that are not connected to through interconnects may be formed on the upper surface 30a of the insulating layer 30.

As described above, the electrode 40 is provided on the insulating layer 30, and one side thereof is not covered with the insulating layer 30. The electrode 40 includes a recess 40x that opens on the one side. The depth of the recess 40x is, for example, about 3 μm or more and 40 μm or less. In the example illustrated in FIG. 1, the one side of the electrode 40 is the same side as the upper surface 41a of the pad 41. In the example illustrated in FIG. 1, the recess 40x is provided in the pad 41 and extends from the pad 41 to the through interconnect 42. The material of the electrode 40 may be, for example, copper (Cu) or the like. The electrode 40 may have a laminated structure comprised of a plurality of metal layers.

The surface-treated layer may be formed only on the upper surface 41a of the pad 41, or formed on the upper surface 41a and the side surface of the pad 41. Examples of the surface-treated layer include an Au layer, an Ni/Au layer (a metal layer in which an Ni layer and an Au layer are laminated in this order), an Ni/Pd/Au layer (a metal layer in which an Ni layer, a Pd layer, and an Au layer are laminated in this order), and an Au/Pd/Au layer (a metal layer in which an Au layer, a Pd layer, and an Au layer are laminated in this order). In addition, only the upper surface 41a of the pad 41 or the upper surface 41a and the side surface of the pad 41 may be subjected to an oxidation prevention treatment such as an organic solderability preservative (OSP) treatment.

The external connection terminal 50 is provided on the one side of the electrode 40. The external connection terminal 50 includes a first conductor 51 filling the recess 40x and a second conductor 52 provided on the first conductor 51. The upper surface 51a of the first conductor 51 is flush with the upper surface 41a of the pad 41, or protrudes beyond the upper surface 41a toward the second conductor 52. The second conductor 52 continuously covers the upper surface 51a of the first conductor 51 and the upper surface 41a of the pad 41.

The melting point of the first conductor 51 is higher than the melting point of the second conductor 52. The first conductor 51 and the second conductor 52 are, for example, solders having different melting points. Examples of the solders include tin-antimony (Sn—Sb), tin-lead (Sn—Pb), tin-copper (Sn—Cu), tin-silver-copper (Sn—Ag—Cu), tin-bismuth (Sn—Bi), and tin-silver (Sn—Ag). Among these, materials may be selected such that the melting point of the first conductor 51 is higher than the melting point of the second conductor 52.

A combination of the first conductor 51 and the second conductor 52 may be, for example, tin-antimony and tin-silver-copper, tin-lead and tin-bismuth, tin-copper and tin-silver, and the like. The melting point of tin-antimony is about 240° C. to 260° C., and the melting point of tin-silver-copper is about 217° C. to 226° C. The melting point of tin-lead is about 183° C., and the melting point of tin-bismuth is about 138° C. to 174° C. The melting point of tin-copper is about 227° C. to 229° C., and the melting point of tin-silver is about 221° C. to 223° C.

The first conductor 51 may be a metal sintered material. Examples of the metal sintered material include a copper sintered material and a silver sintered material. The sintering temperature of copper is about 250° C. to 300° C. The melting point of copper after sintering is about 1085° C. The sintering temperature of silver is about 230° C. to 280° C. The melting point of silver after sintering is about 962° C. With a metal sintered material being used as the first conductor 51, any of the above-described solders may be used as the second conductor 52.

The specific resistance of the first conductor 51 is preferably higher than the specific resistance of the second conductor 52. By making the specific resistance of the first conductor 51 higher than the specific resistance of the second conductor 52, it is possible to achieve uniform distribution of current in the external connection terminal 50. Among the above-described materials, examples of a combination of the first conductor 51 and the second conductor 52 with which the specific resistance of the first conductor 51 becomes higher than the specific resistance of the second conductor 52 include a tin-based solder (i.e., tin-antimony, tin-silver-copper, tin-lead, tin-bismuth, tin-copper, or tin-silver) and a silver sintered material, tin alone and a copper sintered material, bismuth alone and tin alone, and the like.

A solder resist layer may be formed on the upper surface 30a of the insulating layer 30, and may have an opening that exposes part or all of each electrode 40. In this case, the external connection terminal 50 may be formed on the electrode 40 exposed through the opening.

### [Method of Making Interconnect Substrate]

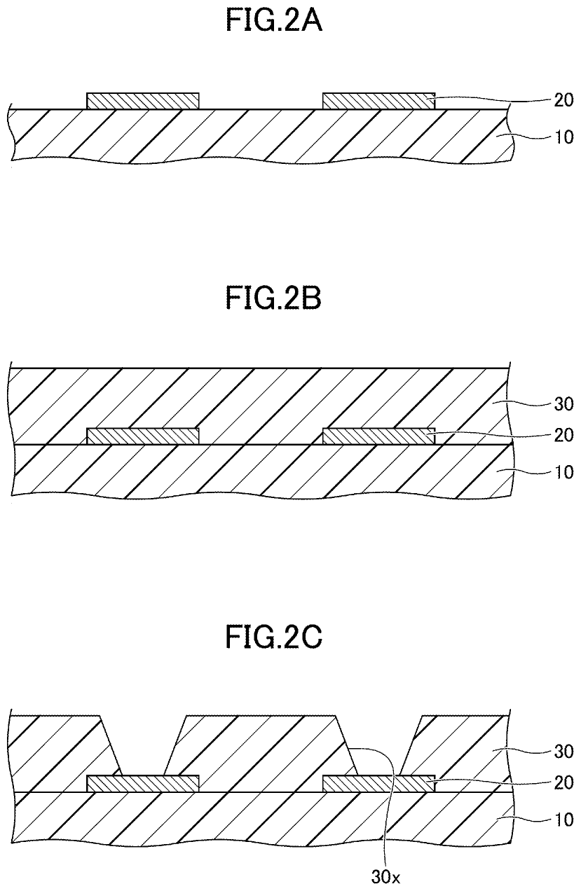

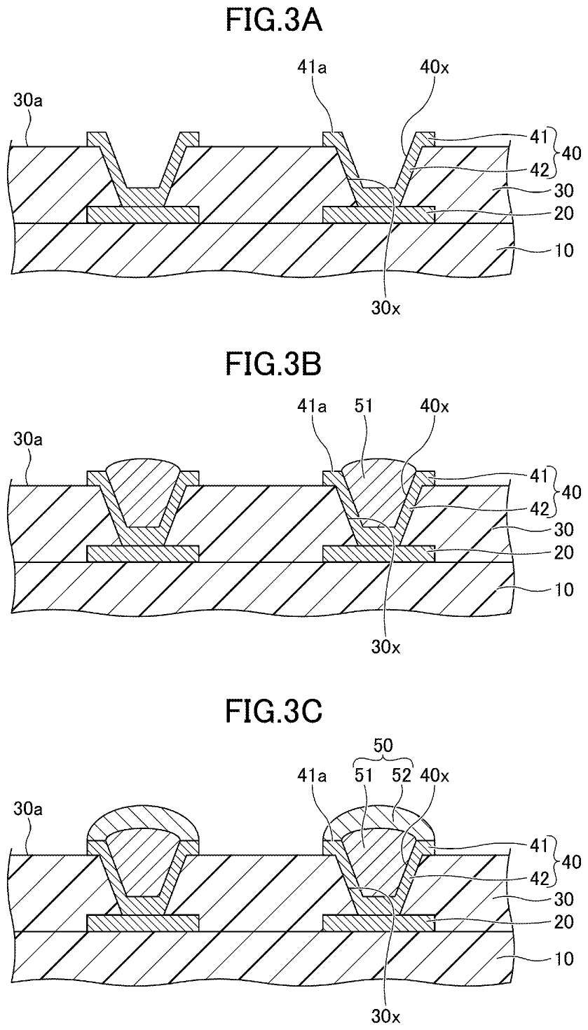

In the following, a method of making the interconnect substrate according to the first embodiment will be described. FIGS. 2A through 2C and FIGS. 3A through 3C are drawings illustrating an example of the steps of making the interconnect substrate according to the first embodiment. In the present embodiment, the steps of forming a single interconnect substrate is shown. Alternatively, a plurality of portions to become respective interconnect substrates may be first formed, and may then be subjected to singulation to produce individual interconnect substrates.

In the step illustrated in FIG. 2A, an insulating layer 10 is prepared, and an interconnect layer 20 is formed on the upper surface of the insulating layer 10 by a well-known sputtering method, plating method, or the like.

In the step illustrated in FIG. 2B, an insulating layer 30 that covers the interconnect layer 20 is formed on the insulating layer 10. Specifically, for example, a thermosetting epoxy-based insulating resin film is prepared as the insulating layer 30, and is laminated on the upper surface of the insulating layer 10 to cover the interconnect layer 20. Then, while pressing the laminated insulating layer 30, the insulating layer 30 is cured by heat at a curing temperature or higher.

Alternatively, as the material of the insulating layer 30, for example, thermosetting epoxy-based insulating resin liquid or paste is prepared, and is applied to the upper surface of the insulating layer 10 by spin coating or the like to cover the interconnect layer 20. Then, the applied insulating resin is cured by heat at a curing temperature or higher to form the insulating layer 30.

In the step illustrated in FIG. 2C, a via hole 30x that extends through the insulating layer 30 and exposes the upper surface of the interconnect layer 20 is formed in the insulating layer 30. The via hole 30x may be formed by, for example, a laser processing method using a CO₂ laser or the like. The via hole 30x formed by the laser processing method becomes a recess having an inverted truncated conical shape in which the diameter of the opening on the side where the electrode 40 is to be formed is larger than the diameter of the bottom opening at the upper surface of the interconnect layer 20. After the via hole 30x is formed by the laser processing method, a desmear process is preferably performed to remove the residual resin of the insulating layer 30 adhering to the upper surface of the interconnect layer 20 exposed at the bottom of the via hole 30x.

In the step illustrated in FIG. 3A, an electrode 40 including a pad 41 and a through interconnect 42 is formed in the insulating layer 30. The pad 41 is electrically connected to the interconnect layer 20 via the through interconnect 42. The electrode 40 including the pad 41 and the through interconnect 42 may be seamlessly formed by using, for example, a semi-additive method.

To be more specific, a seed layer is continuously formed on the upper surface of the interconnect layer 20 exposed at the bottom of the via hole 30x, the inner surface of the via hole 30x, and the upper surface 30a of the insulating layer 30 by electroless plating or sputtering. Next, a resist layer having an opening corresponding to the pad 41 is formed on the seed layer. Then, an electrolytic plating layer is formed in the opening of the resist layer by an electrolytic plating method using the seed layer as a power feeding layer. At this time, the recess 40x is formed, as a depression relative to the surrounding area, in the center of the upper surface of the electrolytic plating layer. The recess 40x is formed as a result of the plating conditions for forming the electrode 40, the aspect ratio of the via hole 30x, and the like. The aspect ratio is defined as the ratio of the maximum depth to the maximum width of the opening of the via hole 30x.

Subsequently, the resist layer is removed, and a portion of the seed layer that is not covered with the electrolytic plating layer is removed by etching using the electrolytic plating layer as a mask. As a result, the electrode 40 made by stacking the electrolytic plating layer on the seed layer is formed. As the seed layer, a laminated film comprised of a titanium layer and a copper layer stacked in this order may be used. The electrolytic plating layer may be, for example, a copper layer. The thickness of the seed layer may be, for example, about 0.2 μm to 0.4 μm. The electrolytic plating layer located on the upper surface 30a of the insulating layer 30 may be, for example, about 10 μm to 200 μm in thickness.

In the step illustrated in FIGS. 3B and 3C, an external connection terminal 50 is formed on one side of the electrode 40. First, as shown in FIG. 3B, a first conductor 51 is formed to fill the recess 40x of the electrode 40. Specifically, a first conductive material to become the first conductor 51 is prepared, and the recess 40x of the electrode 40 is filled with the first conductive material. In the illustrated example, first solder paste is used as the first conductive material. The first solder paste may be applied by, for example, screen-printing or the like to fill the recess 40x of the electrode 40. Next, in reflow soldering or the like, the first solder paste is melted by heat at a first temperature higher than the melting point of the first solder paste. Then, the first solder paste solidifies by cooling, thereby becoming the first conductor 51. As the first conductive material, a solder ball may alternatively be used in place of the first solder paste. As the first conductive material, a metal paste that becomes a sintered material by heating may alternatively be used in place of the first solder paste. The melting point of the first conductive material is the same as the melting point of the first conductor 51.

Subsequently, as illustrated in FIG. 3C, a second conductor 52 is formed on the first conductor 51. Specifically, a second conductive material to become the second conductor 52 is prepared. In the illustrated example, second solder paste having a lower melting point than the first conductive material is used as the second conductive material. The second solder paste may be applied to the first conductor 51 by screen printing or the like, for example. In reflow soldering or the like, the second solder paste is melted by heat at a second temperature higher than the melting point of the second solder paste and lower than the melting point of the first conductive material. The second solder paste then solidifies by cooling, thereby becoming the second conductor 52. As a result, the external connection terminal 50 including the first conductor 51 filling the recess 40x and the second conductor 52 provided on the first conductor 51 is formed on the one side of the electrode 40. As the second conductive material, a solder ball may alternatively be used in place of the second solder paste. The melting point of the second conductive material is the same as the melting point of the second conductor 52.

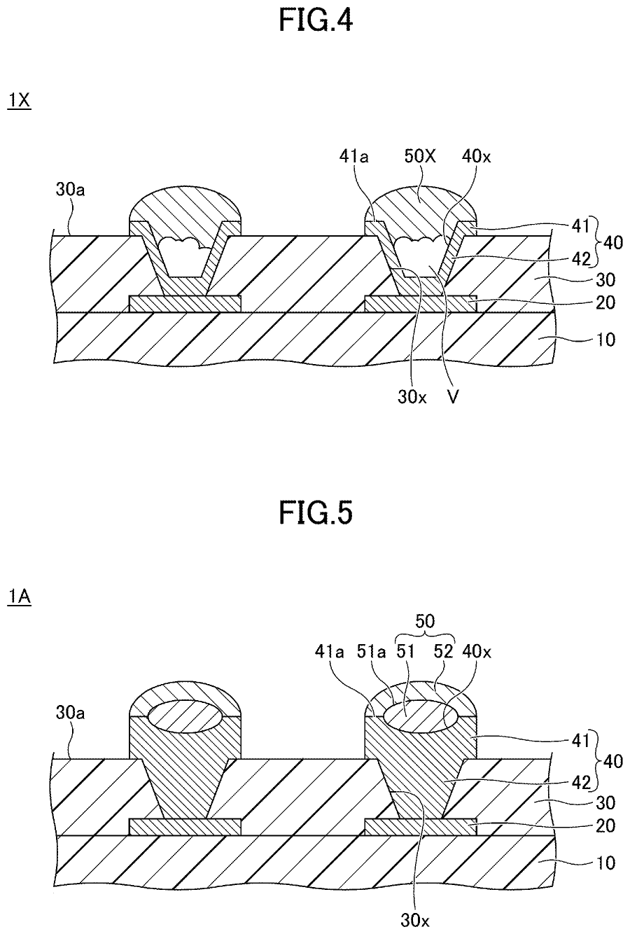

FIG. 4 is a partial cross-sectional view illustrating an example of an interconnect substrate according to a comparative example. Referring to FIG. 4, an interconnect substrate 1X according to the comparative example differs from the interconnect substrate 1 in that the external connection terminal 50 is replaced with an external connection terminal 50X. The external connection terminal 50X is made of only one conductive material.

In the case in which the external connection terminal 50X is made of only one conductive material, a recess 40x may not be sufficiently filled with solder paste or the like during reflow soldering. A void V may thus be generated in the external connection terminal 50x and located near the bottom of the recess 40X. For example, the void V is generated from a space existing in the solder paste or generated by vaporization of a flux contained in the solder paste. When the void V remains in the external connection terminal 50X after the reflow soldering, an increase in electrical resistance, a decrease in mechanical strength, and the like occurs, which results in reduction in the reliability of connection of the external connection terminal 50X. In the case of an interconnect substrate having a large current flowing therethrough, the current may be concentrated around the void V, thereby creating the risk of accelerating the destruction of the external connection terminal 50X.

In contrast, the external connection terminal 50 of the interconnect substrate 1 is made of two types of conductive material. Because of this, a relatively small amount of first conductive material to become the first conductor 51 is used when forming the first conductor 51 in the recess 40x. As a result, the recess 40x may reliably be filled with the first conductor 51, which reduces the likelihood of occurrence of a void in the first conductor 51.

In the interconnect substrate 1, the second conductor 52 is formed on the solidified first conductor 51 and made of the second conductive material having a lower melting point than the first conductor 51. With this arrangement, when the second conductive material is reflowed, the first conductor 51 filling the recess 40x is not melted again. As a result, it is possible to prevent the overflowing of solder and the like, thereby preventing a void from being generated when the second conductive material is reflowed.

As described above, the interconnect substrate 1 is unlikely to have a void in the external connection terminal 50. As a result, an increase in electrical resistance, a decrease in mechanical strength, and the like are less likely to occur in the external connection terminal 50, which enables the improvement of connection reliability when the external connection terminal 50 is connected to a semiconductor chip. Further, even in an interconnect substrate having a large current flowing therethrough, the current is less likely to be concentrated in the external connection terminal 50. Therefore, breakage of the external connection terminal 50 can be suppressed, and connection reliability when connected to a semiconductor chip can be improved.

Further, in the external connection terminal 50, when the specific resistance of the first conductor 51 is higher than the specific resistance of the second conductor 52, the first conductor 51 having the higher specific resistance can serve to uniformly distribute current in the external connection terminal 50. It is thus possible to further reduce the concentration of current in the external connection terminal 50. This arrangement further enables the improvement of connection reliability for connection to a semiconductor chip.

### <First Variation of First Embodiment>

The first variation of the first embodiment is directed to an example in which a recess is provided only in a pad. In the first variation of the first embodiment, a description of the same components as those of the previously described embodiment may be omitted.

FIG. 5 is a partial cross-sectional view illustrating an example of an interconnect substrate according to the first variation of the first embodiment. Referring to FIG. 5, the pad 41 is thicker in an interconnect substrate 1A than in the interconnect substrate 1. As a result, the recess 40x in the interconnect substrate 1A is provided only in the pad 41. In this manner, the recess 40x may extend from the pad 41 to the through interconnect 42 as in the interconnect substrate 1, or may be provided only in the pad 41 as in the interconnect substrate 1A. In either case, the advantageous effect obtained by providing the external connection terminal 50 comprised of the first conductor 51 and the second conductor 52 is the same.

When the protruding portion of the electrode 40 protruding from the upper surface 30a of the insulating layer 30 is relatively thick as illustrated in FIG. 5, the protruding portion may be referred to as a post or a pillar. In the present application, however, a portion where the external connection terminal is formed is referred to as a pad regardless of the thickness of the protruding portion.

### <Second Variation of First Embodiment>

The second variation of the first embodiment is directed to an example of an interconnect substrate having only one insulating layer. In the second variation of the first embodiment, a description of the same components as those of the previously described embodiments may be omitted.

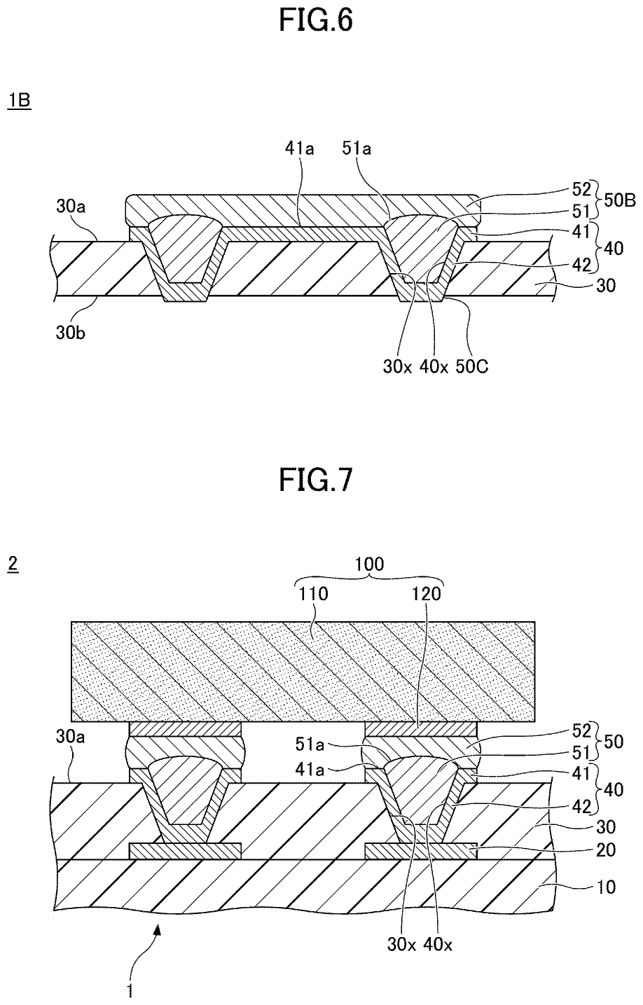

FIG. 6 is a partial cross-sectional view illustrating an example of an interconnect substrate according to the second variation of the first embodiment. Referring to FIG. 6, an interconnect substrate 1B includes one insulating layer 30. Part of the upper surface 30a and all of the lower surface 30b of the insulating layer 30 are exposed to the outside of the interconnect substrate 1B. The interconnect substrate 1B has an external connection terminal 50B. The interconnect substrate 1B is, for example, a flexible substrate.

In the interconnect substrate 1B, the pads 41 of two adjacent electrodes 40 extend on the upper surface 30a of the insulating layer 30 and are connected to each other. The interconnect substrate 1B has external connection terminals 50B including first conductors 51 provided on the respective electrodes 40 and a second conductor 52 provided on the first conductors 51 to connect the first conductors 51 to each other. In each of the electrodes 40, the through interconnect 42 protrudes from the lower surface 30b of the insulating layer 30. The portion of the through interconnect 42 protruding from the lower surface 30b of the insulating layer 30 serves as a second external connection terminal 50C.

In the case of the interconnect substrate 1B, an electrode 40 itself may be used as an external connection terminal at one end thereof at which the external connection terminal 50B is not formed, among the two ends of the electrode 40 extending through the single insulating layer 30. It may be noted that the interconnect substrate 1B does not necessarily require the structure in which the plurality of electrodes 40 are connected to each other.

### <Example of Application of First Embodiment>

An example of application of the first embodiment is directed to a semiconductor apparatus in which a semiconductor chip is mounted on an interconnect substrate. In the example of application of the first embodiment, a description of the same components as those in the previously described embodiments may be omitted.

FIG. 7 is a cross-sectional view illustrating an example of a semiconductor apparatus according to a first example of application of the first embodiment. Referring to FIG. 7, a semiconductor apparatus 2 includes the interconnect substrate 1 illustrated in FIG. 1 and a semiconductor chip 100. The chip 100 is mounted in an opposing relationship to the upper surface 30a of the insulating layer 30 of the interconnect substrate 1 and is electrically connected to the external connection terminals 50.

The semiconductor chip 100 is obtained by forming a semiconductor integrated circuit (not shown) or the like on a thinned semiconductor substrate 110 made of silicon or the like, for example. An electrode 120 electrically connected to the semiconductor integrated circuit (not shown) is formed on the semiconductor substrate 110. The electrode 120 may be made of, for example, copper or aluminum.

The electrode 120 is electrically connected to the electrode 40 of the interconnect substrate 1 via the external connection terminal 50. An underfill resin may fill the gap between the semiconductor substrate 110 and the interconnect substrate 1.

In this manner, the semiconductor apparatus 2 can be made by mounting a semiconductor chip on the interconnect substrate 1 according to the first embodiment. In the semiconductor apparatus 2, the semiconductor chip 100 may be connected to the interconnect substrate 1 with high reliability via the external connection terminals 50 in which the likelihood of generation of voids is reduced.

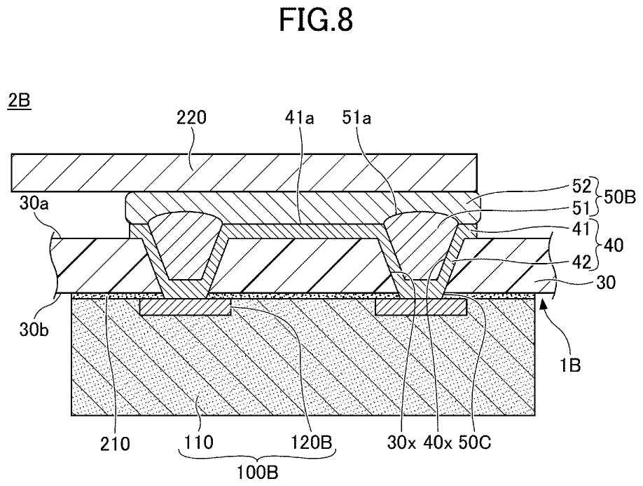

FIG. 8 is a cross-sectional view illustrating an example of a semiconductor apparatus according to a second example of application of the first embodiment. Referring to FIG. 8, a semiconductor apparatus 2B includes the interconnect substrate 1B illustrated in FIG. 6, a semiconductor chip 100B, an adhesive layer 210, and a bus bar 220. The semiconductor chip 100B is mounted in an opposing relationship to the lower surface 30b of the insulating layer 30 of the substrate 1B and is electrically connected to the second external connection terminals 50C.

Electrodes 120B electrically connected to a semiconductor integrated circuit (not shown) are formed on the semiconductor substrate 110 of the semiconductor chip 100B. The electrodes 120B may be made of, for example, copper or aluminum. The semiconductor chip 100B is bonded to the lower surface 30b of the insulating layer 30 of the interconnect substrate 1B via the adhesive layer 210 with the electrodes 120B facing the interconnect substrate 1B. The thickness of the adhesive layer 210 may be, for example, about 20 μm to 40 μm.

The second external connection terminals 50C of the interconnect substrate 1B penetrate the adhesive layer 210 and are electrically connected to the electrodes 120B of the semiconductor chip 100B. The second external connection terminals 50C and the electrodes 120B may be directly bonded to each other by intermetallic bonding or the like, or may be bonded to each other via solder or the like.

The bus bar 220 is electrically connected to the external connection terminals 50B of the interconnect substrate 1B. The bus bar 220 is made of a metal such as copper, for example.

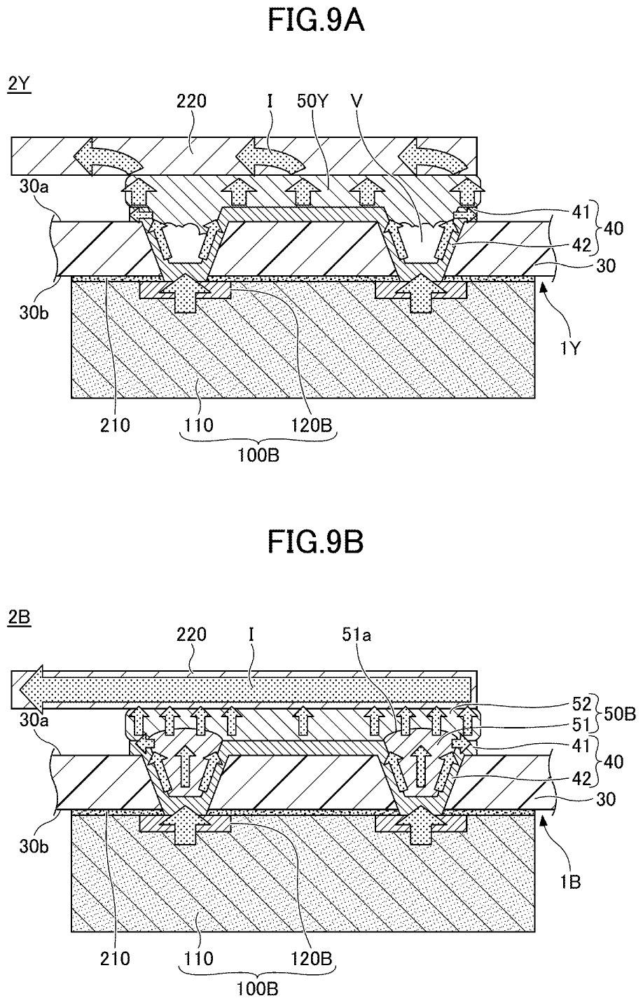

FIGS. 9A and 9B are drawings illustrating the flows of current. The arrows indicate current flows. FIG. 9A illustrates a semiconductor apparatus 2Y according to a comparative example. The semiconductor apparatus 2Y includes an interconnect substrate 1Y and the semiconductor chip 100B. The interconnect substrate 1Y differs from the interconnect substrate 1B in that the external connection terminals 50B are replaced with external connection terminals 50Y. The external connection terminals 50Y are formed of only one type of conductive material. As a result, voids V are generated in the external connection terminals 50Y. Since currents I in the semiconductor apparatus 2Y do not uniformly flow through the inside of the external connection terminals 50Y and the currents I are concentrated in the surrounding areas of the voids V, the destruction of the external connection terminals 50Y may be accelerated.

In contrast, in the case of the semiconductor apparatus 2B illustrated in FIG. 9B, the external connection terminals 50B of the interconnect substrate 1B are formed of two kinds of conductive material, which reduces the occurrence of voids in the first conductors 51. Since currents I in the semiconductor apparatus 2B uniformly flow through the inside of the external connection terminals 50B, the currents I are less likely to be concentrated, which reduces the risk that the destruction of the external connection terminals 50B is accelerated.

According to at least one embodiment, it is possible to provide an interconnect substrate for which the reliability of connection with a semiconductor chip is improved.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

The present disclosures non-exhaustively include the subject matter set out in the following clause:

[Clause 1] A method of making an interconnect substrate including an insulating layer, an electrode disposed on the insulating layer and having a first surface not covered with the insulating layer, and an external connection terminal disposed on the first surface of the electrode, the electrode having a recess in the first surface, the method comprising:
forming the external connection terminal includes:
filling the recess with a first conductive material;
melting the first conductive material by heat at a first temperature, followed by solidifying the first conductive material by cooling to form a first conductor;
depositing a second conductive material on the first conductor; and
melting the second conductive material by heat at a second temperature, followed by solidifying the second conductive material by cooling to form a second conductor,
wherein a melting point of the first conductive material is higher than a melting point of the second conductive material, and
wherein the first temperature is higher than the melting point of the first conductive material, and the second temperature is higher than the melting point of the second conductive material and lower than the melting point of the first conductive material.

What is claimed is:

1. An interconnect substrate comprising:
an insulating layer;
an electrode disposed on the insulating layer and having a first surface not covered with the insulating layer; and
an external connection terminal disposed on the first surface of the electrode;
wherein the electrode has a recess in the first surface,
wherein the external connection terminal includes a first conductor filling the recess and a second conductor disposed on the first conductor, and a melting point of the first conductor is higher than a melting point of the second conductor, and
wherein a metal material of the electrode is different from a metal material of the first conductor.

2. The interconnect substrate as claimed in claim 1, wherein a specific resistance of the first conductor is higher than a specific resistance of the second conductor.

3. The interconnect substrate as claimed in claim 1, wherein the first conductor and the second conductor are solder.

4. The interconnect substrate as claimed in claim 1, wherein the first conductor is a metal sintered material, and the second conductor is solder.

5. The interconnect substrate as claimed in claim 1, wherein the electrode includes a pad disposed on one surface of the insulating layer and a through interconnect connected to the pad and disposed in the insulating layer, and
wherein the recess is formed in the pad and extends from the pad to the through interconnect.

6. The interconnect substrate as claimed in claim 5, wherein the through interconnect protrudes from an opposite surface of the insulating layer to serve as a second external connection terminal.

7. A semiconductor apparatus comprising:
the interconnect substrate of claim 5; and
a semiconductor chip mounted in an opposing relationship to the one surface of the insulating layer and electrically connected to the external connection terminal.

8. A semiconductor apparatus comprising:
the interconnect substrate of claim 6; and
a semiconductor chip mounted in an opposing relationship to the opposite surface of the insulating layer and electrically connected to the second external connection terminal.

9. The semiconductor apparatus as claimed in claim 8, further comprising a bus bar electrically connected to the external connection terminal.
